(19) United States
(12) Patent Application Publication
(10) Pub. No.: US 2022/0140470 A1
(43) Pub. Date: May 5, 2022

(54) ELECTRONIC DEVICE

(71) Applicants: Inventec (Pudong) Technology Corporation, Shanghai (CN); INVENTEC CORPORATION, Taipei City (TW)

(72) Inventor: Chih-Cheng LI, TAIPEI CITY (TW)

(21) Appl. No.: 17/131,800

(22) Filed: Dec. 23, 2020

(30) Foreign Application Priority Data
Nov. 5, 2020 (CN) 202011224086.8

(51) Int. Cl. H01Q 1/24; G06F 1/16

(52) U.S. Cl. CPC H01Q 1/243; G06F 1/1698; G06F 1/1681

(57) ABSTRACT

An electronic device includes a first body, a second body, a hinge, and at least one flexible board. The first body includes a first casing, a panel, and at least one antenna structure. The panel and the at least one antenna structure are disposed in the first casing. The second body includes a second casing, a keyboard, and a radio frequency module. The keyboard and the radio frequency module are disposed in the second casing. The hinge is used to connect the first body and the second body, and the hinge includes a space. The at least one flexible board is coupled to the at least one antenna structure of the first body and the radio frequency module of the second body through the space of the hinge.

### CROSS-REFERENCE TO RELATED APPLICATION

This application claims priority to China Application Serial Number 202011224086.8, filed Nov. 5, 2020, which is herein incorporated by reference in its entirety.

### BACKGROUND

### Field of Invention

The present disclosure relates to an electronic device. More particularly, the present disclosure relates to an electronic device having an antenna structure.

### Description of Related Art

In order to meet requirements of sizes reduction of products, a space of coaxial cables which is coupled to antennas and radio frequency modules is gradually reduced. At the same time, in response to requirements of the fifth-generation mobile communication technology, reception and transmission loss of high frequency signals are considered in the design of products. Sizes and flexibility of conventional coaxial cables may not meet requirements of configurations of products in the future.

For the foregoing reason, there is a need to provide some other antenna structure to solve the problems of the prior art.

### SUMMARY

One aspect of the present disclosure provides an electronic device. The electronic device includes a first body, a second body, a hinge, and at least one flexible board. The first body includes a first casing, a panel and at least one antenna structure. The panel and the at least one antenna structure are disposed in the first casing. The second body includes a second casing, a keyboard and a radio frequency module. The keyboard and the radio frequency module are disposed in the second casing. The hinge is configured to connect between the first body and the second body, and the hinge includes a space. The at least one flexible board is coupled to the at least one antenna structure of the first body and the radio frequency module of the second body through the space of the hinge.

These and other aspects of the present disclosure will become apparent from the following description of the preferred embodiment taken in conjunction with the following drawings, although variations and modifications therein may be effected without departing from the spirit and scope of the novel concepts of the disclosure.

It is to be understood that both the foregoing general description and the following detailed description are by examples, and are intended to provide further explanation of the present disclosure as claimed.

### BRIEF DESCRIPTION OF THE DRAWINGS

The invention can be more fully understood by reading the following detailed description of the embodiment, with reference made to the accompanying drawings as follows:

FIG. 1 depicts a schematic diagram of a perspective view of an electronic device according to one embodiment of the present disclosure;

FIG. 2 depicts a schematic diagram of a closed state of an electronic device according to one embodiment of the present disclosure; and

FIG. 3 depicts a schematic diagram of a flipping cover state of an electronic device according to one embodiment of the present disclosure.

### DETAILED DESCRIPTION

Reference will now be made in detail to the present embodiments of the invention, examples of which are illustrated in the accompanying drawings. Wherever possible, the same reference numbers are used in the drawings and the description to refer to the same or like parts.

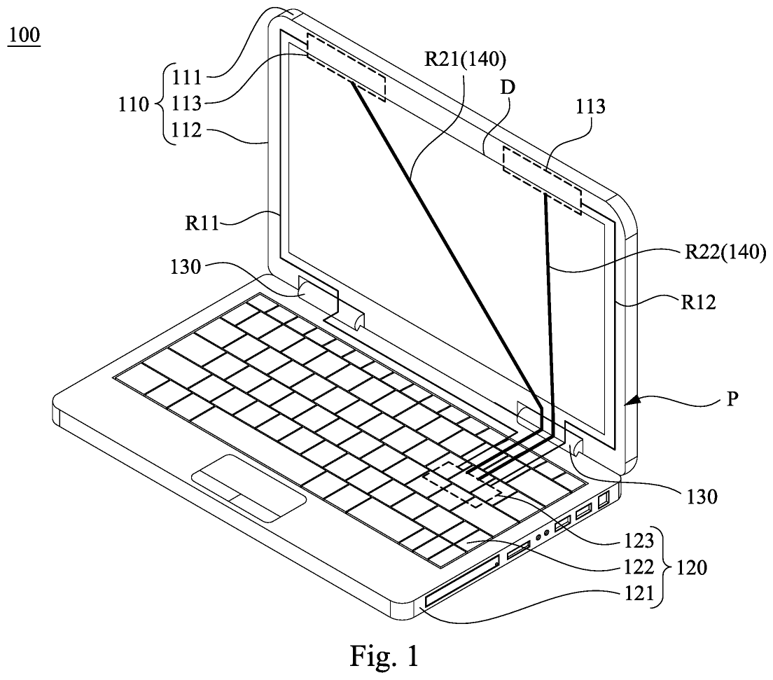

FIG. 1 depicts a schematic diagram of a perspective view of an electronic device according to one embodiment of the present disclosure. In some embodiments, an electronic device 100 includes laptops, flip phones, and handle game consoles.

In some embodiments, as shown in FIG. 1, the electronic device 100 includes a first body 110, a second body 120, a hinge 130, and at least one flexible board 140.

In some embodiments, the first body 110 includes a first casing 111, a panel 112, and at least one antenna structure 113. The panel 112 and the at least one antenna structure 113 are disposed in the first casing 111.

In some embodiments, the second body 120 includes a second casing 121, a keyboard 122, and a radio frequency module 123. The keyboard 122 and the radio frequency module 123 are disposed in the second casing 121.

In some embodiments, the hinge 130 is configured to connect the first body 110 and the second body 120, and the hinge 130 includes a space.

In some embodiments, the at least one flexible board 140 is coupled to the at least one antenna structure 113 of the first body 110 and the radio frequency module 123 of the second body 120 through the space of the hinge 130.

In some embodiments, the at least one flexible board 140 includes liquid crystalline polyester (LCP). It should be noted that the difference between a dielectric loss value of the LCP materials in the high frequency band and a dielectric loss value of the LCP materials in the normal frequency band is very small, and the LCP materials are suitable to transmit a signal in a microwave band or a signal in a millimeter wave band. In addition, a thermal expansion coefficient of the LCP materials is very small. Therefore, the LCP materials are suitable for transmission lines of high frequency technology.

In addition, the at least one flexible board 140 is mixed with discontinuous polytetrafluoroethene (PTFE) based on the LCP materials. Due to the demand for high frequency technology is that a huge amount of data should be transmitted in a short time, the characteristics of dielectric, mechanical, heat resistance, and stability of the LCP materials are considered so as to ensure that data will not be interfered and loss during the transmission line. It should be noted that the PTFE is mixed in the at least one flexible board 140 to reduce an insertion loss of the at least one flexible board 140 due to the characteristics of PTFE.

In some embodiments, the at least one antenna structure 113 is a 4G antenna or a 5G antenna. In some embodiments, a length of the at least one antenna structure 113 is equal to or smaller than 1 mm. In some embodiments, the at least one antenna structure 113 is composed of a conductive layer of a printed circuit board. It should be noted that the at least one antenna structure 113 and the printed circuit board can be formed during the manufacturing process, which makes designs of circuit elements more easy, saves process cost, and provides multiple choices in circuit layouts.

In some embodiments, the first casing 111 and the second casing 121 include a metal. For example, the first casing 111 and the second casing 121 are metal casings. It is noted that the present disclosure is not limited to the above-mentioned embodiments and FIG. 1, and production materials of the first casing 111 and the second casing 121 can be designed according to actual needs.

In some embodiments, the panel 112 includes a display area D and a peripheral area P. The peripheral area P is located outside the display area D. The at least one antenna structure 113 can be disposed in the display area D or the peripheral area P. In other words, the at least one antenna structure 113 can be located in anywhere of the display area D and the peripheral area P, and the present disclosure is not limited to the embodiments shown in FIG. 1. In some embodiments, a number of the at least one antenna structure 113 is not limited to that shown in FIG. 1.

In some embodiments, if the at least one antenna structure 113 is located in the display area D, the at least one flexible board 140 is extended from the hinge 130 to the display area D, and is coupled to the at least one antenna structure 113. In some embodiments, the at least one flexible board 140 is coupled to the antenna structure 113 at the left side shown in figure by a route R21 which is extended to the display area D. In some embodiments, the at least one flexible board 140 is coupled to the antenna structure 113 on the right side shown in figure by a route R22 which is extended to the display area D. It should be noted that the use of coaxial cables in conventional technology makes panels crack and generate water patterns due to the coaxial cables being thick. Therefore, the coaxial cable is only coupled to the at least one antenna structure 113 along a route R11 or a route R12 in the peripheral area P. The at least one flexible board 140 of the present disclosure is coupled to the at least one antenna structure 113 along the route R21 or the route R22 in the display area. Compared to a length of the coaxial cable along the route R11, a length of the at least one flexible board 140 along the route R21 is shorter. Similarly, compared to a length of the coaxial cable along the route R12, a length of the at least one flexible board 140 along the route R22 is shorter. Therefore, when the length of the transmission line of the at least one flexible board 140 of the present disclosure is short, an insertion loss of a high frequency is small.

In some embodiments, a shape of the route R21 or the route R22 is not limited to a straight line. It should be noted that the present disclosure is not limited to the above-mentioned embodiments, a length of the at least one flexible board flexible board 140 is designed according to actual needs.

In some embodiments, the above flexible board 140 is located close to the first casing 111 and the second casing 121. The design of the flexible board 140 not only reduces the loss during the transmission line, but also increases a space of an electronic device.

In some embodiments, the hinge 130 includes hinged hinges, dual axis hinges, and monolithic hinges. It should be noted that the present disclosure is not limited to the above-mentioned embodiments and FIG. 1, the hinge 130 is designed according to actual needs.

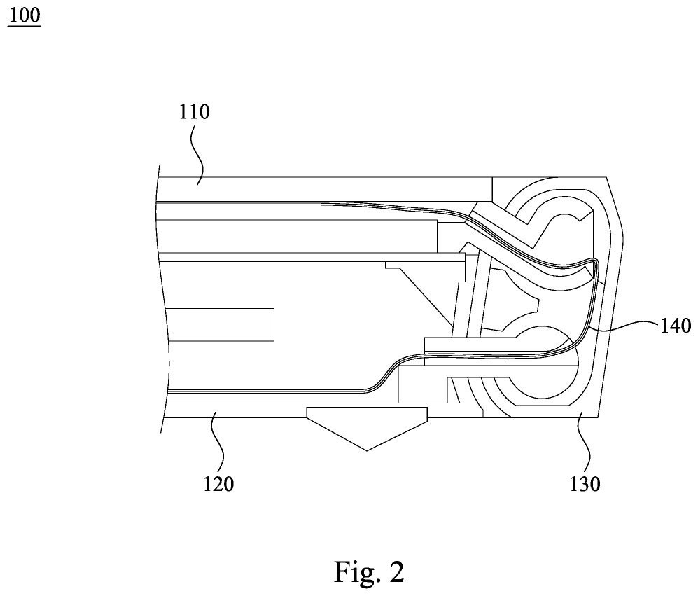

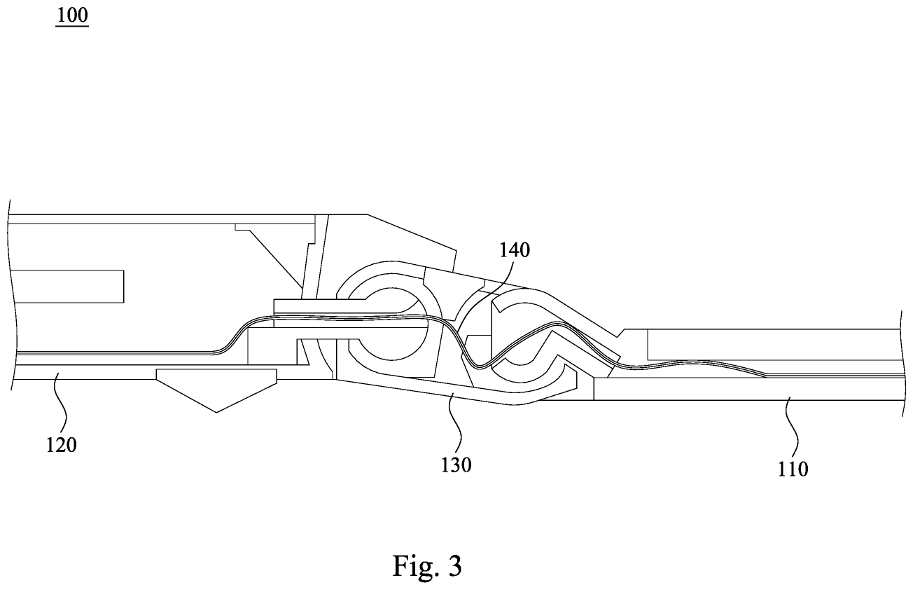

In some embodiments, in order to facilitate the understanding of the structure of the electronic device of the present disclosure, please refer to FIG. 2 and FIG. 3 together. FIG. 2 depicts a schematic diagram of a closed state of an electronic device according to one embodiment of the present disclosure. FIG. 3 depicts a schematic diagram of a flipping cover state of an electronic device according to one embodiment of the present disclosure. In some embodiments, FIG. 2 is schematic side view corresponding to the electronic device 100 in a closed state. In some embodiments, FIG. 3 is schematic side view corresponding to the electronic device 100 in a flipping over state.

In some embodiments, please refer to FIG. 2 and FIG. 3, whether the electronic device 100 is in the flipping over state or the electronic device 100 is in the closed state, the at least flexible board 140 can be adapted to the internal structure of the hinge 130, and be adapted to structural changes. It should be noted that the appropriate space size within the hinge 130 allows the at least flexible board 140 to pass through and fold. The thickness of the at least flexible board 140 of the present disclosure is thinner than the thickness of conventional cables.

Based on the above embodiments, the present disclosure provides an electronic device to improve a length of a transmission line between antennas and radio frequency modules. The use of flexible boards fits in an internal structure of an electronic device, makes a length of transmission line shorter, and reduces a loss of transmission signals.

It will be apparent to those skilled in the art that various modifications and variations can be made to the structure of the present invention without departing from the scope or spirit of the invention. In view of the foregoing, it is intended that the present invention cover modifications and variations of this invention provided they fall within the scope of the following claims.

What is claimed is:

1. An electronic device, comprising:
a first body, wherein the first body comprises a first casing, a panel, and at least one antenna structure, wherein the panel and the at least one antenna structure are disposed in the first casing;
a second body, wherein the second body comprises a second casing, a keyboard, and a radio frequency module, wherein the keyboard and the radio frequency module are disposed in the second casing;
a hinge, configured to connect the first body and the second body, wherein the hinge comprises a space; and
at least one flexible board, coupled to the at least one antenna structure of the first body and the radio frequency module of the second body though the space of the hinge.

2. The electronic device of claim 1, wherein the at least one flexible board comprises liquid crystal polymer (LCP).

3. The electronic device of claim 2, wherein the at least one flexible board comprises polytetrafluoroethylene (PTFE).

4. The electronic device of claim 3, wherein the at least one flexible board is configured to transmit a first signal in a microwave band or a second signal in a millimeter wave band.

5. The electronic device of claim 1, wherein the at least one antenna structure comprises one of a 4G antenna and a 5G antenna.

6. The electronic device of claim 5, wherein a length of the at least one antenna structure is equal to or smaller than 1 mm.

7. The electronic device of claim 1, wherein the panel comprises a display area and a peripheral area, wherein the peripheral area is located outside the display area, and the at least one antenna structure is located in the display area or the peripheral area.

8. The electronic device of claim 7, wherein if the at least one antenna structure is in the display area, the at least one flexible board is extended from the hinge to the display area, and is coupled to the at least one antenna structure.

9. The electronic device of claim 1, wherein the first casing and the second casing comprise a metal.

10. The electronic device of claim 1, wherein the at least one antenna structure is composed of a conductive layer of a printed circuit board.
